(19) United States
(12) Patent Application Publication
(10) Pub. No.: US 2026/0082762 A1
(43) Pub. Date: Mar. 19, 2026

(54) LIGHT-EMITTING ELEMENT AND DISPLAY DEVICE

(71) Applicant: Sharp Display Technology Corporation, Kameyama City, Mie (JP)

(72) Inventor: SHINICHI HANDA, Sakai City, Osaka (JP)

(21) Appl. No.: 19/108,432

(22) PCT Filed: Sep. 9, 2022
(86) PCT No.: PCT/JP2022/033881

§ 371 Date: Mar. 4, 2025

(51) Int. Cl. H10K 50/115; H10K 50/15; H10K 50/16

(52) U.S. Cl. CPC H10K 50/115; H10K 50/15; H10K 50/16

(57) ABSTRACT

A light-emitting element includes: a first light-emitting layer provided between a first electrode and a second electrode, and containing a plurality of first quantum dots and a first inorganic matrix material filling spaces between the plurality of first quantum dots; a second light-emitting layer provided between the second electrode and the first light-emitting layer, and containing a plurality of second quantum dots and a second inorganic matrix material filling spaces between the plurality of second quantum dots, the second quantum dots emitting light in a same color as a color of light emitted from the plurality of first quantum dots; and a first intermediate layer provided between the first light-emitting layer and the second light-emitting layer.

### TECHNICAL FIELD

The present disclosure relates to, for example, a light-emitting element.

### BACKGROUND ART

Patent Document 1 discloses a device sandwiched between quantum dots (a light-emitting layer) and a charge transport layer, and provided with an interface layer formed of a metal oxide. The device disclosed in Patent Document 1, which is provided with the interface layer, can reduce quenching that occurs at the interface between the charge transport layer and the light-emitting layer.

### CITATION LIST

### Patent Literature

[Patent Document 1] Japanese Unexamined Patent Application Publication No. 2005-290998

### SUMMARY

### Technical Problem

As to the configuration of the device disclosed in Patent Document 1, the interface layer needs to be thick in order to keep a sufficient distance between the light-emitting layer and the charge transport layer so as to prevent quenching. However, the thick interface layer could inevitably block injection of holes into the light light-emitting layer, or raise the voltage to be applied to the device higher than a desired voltage. Hence, the configuration of the device disclosed in Patent Document 1 has difficulty in increasing the thickness of the interface layer. Thus, the problem is that the device disclosed in Patent Document 1 cannot sufficiently reduce quenching.

### Solution to Problem

A light-emitting element according to an aspect of the present disclosure includes: a first electrode and a second electrode; a first light-emitting layer provided between the first electrode and the second electrode, and containing a plurality of first quantum dots and a first inorganic matrix material filling spaces between the plurality of first quantum dots; a second light-emitting layer provided between the second electrode and the first light-emitting layer, and containing a plurality of second quantum dots and a second inorganic matrix material filling spaces between the plurality of second quantum dots, the second quantum dots emitting light in a same color as a color of light emitted from the plurality of first quantum dots; and a first intermediate layer provided between the first light-emitting layer and the second light-emitting layer.

### Advantageous Effect of Disclosure

An aspect of present disclosure can reduce quenching.

### BRIEF DESCRIPTION OF DRAWINGS

FIG. 1 is a schematic cross-sectional view of a display device according to this embodiment.

FIG. 2 is an energy band diagram of a light-emitting element according to this embodiment.

FIG. 3 is a schematic cross-sectional view of an example of how an inorganic matrix material is formed.

FIG. 4 is a schematic cross-sectional view of an example of how the inorganic matrix material is formed.

FIG. 5 is an energy band diagram of another light-emitting element according to this embodiment.

FIG. 6 is an energy band diagram of yet another light-emitting element according to this embodiment.

FIG. 7 is an energy band diagram of yet another light-emitting element according to this embodiment.

FIG. 8 is an energy band diagram of yet another light-emitting element according to this embodiment.

FIG. 9 is an energy band diagram of yet another light-emitting element according to this embodiment.

FIG. 10 is an energy band diagram of yet another light-emitting element according to this embodiment.

FIG. 11 is an energy band diagram of yet another light-emitting element according to this embodiment.

FIG. 12 is a schematic plan view of the display device according to this embodiment.

### DESCRIPTION OF EMBODIMENT

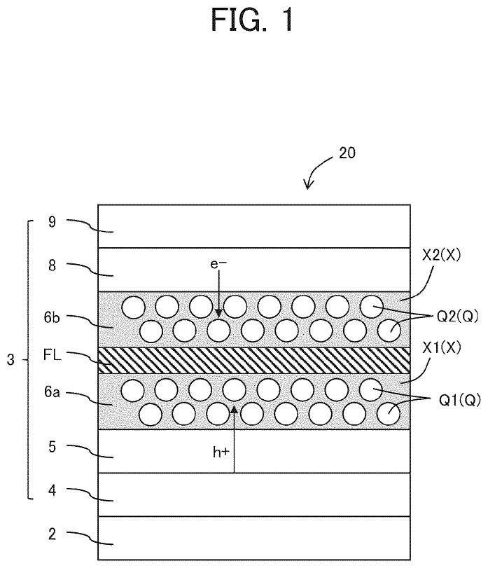

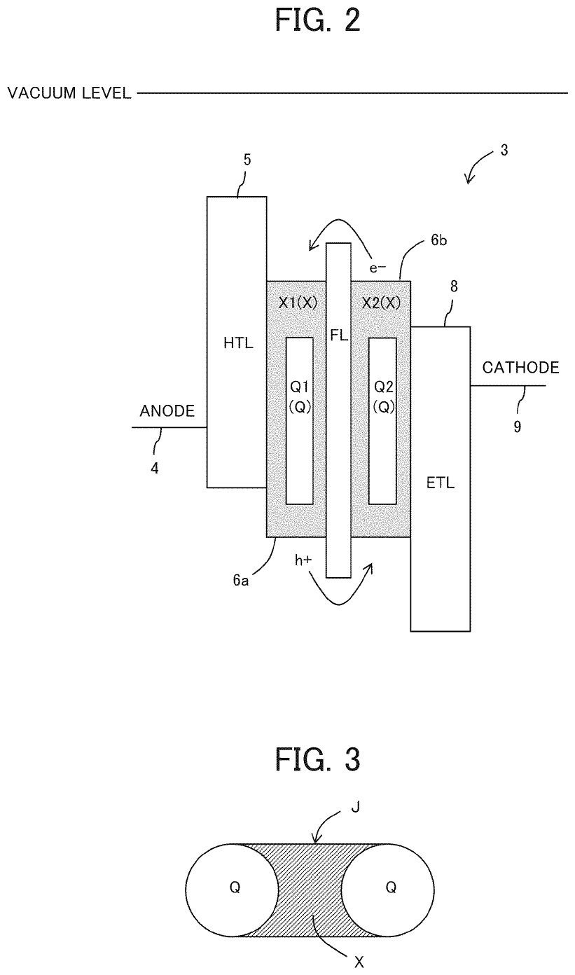

Described below is an embodiment of the present disclosure with reference to the drawings. Note that, throughout the drawings, like reference signs designate identical constituent features. Such constituent features will not be elaborated upon. FIG. 1 is a schematic cross-sectional view of a display device according to this embodiment. FIG. 2 is an energy band diagram of a light-emitting element according to this embodiment. As to the display device 20, the direction from an array substrate 2 toward a light-emitting element 3 may be referred to as “above”, and the opposite direction of “above” may be referred to as “below”.

The display device 20 is, for example, a device to be used for a display of such an appliance as a TV or a smartphone. As illustrated in FIG. 1, the display device 20 includes: the array substrate 2; and the light-emitting element 3. The array substrate 2 is a glass substrate including a not-shown thin-film transistor (TFT) formed for driving the light-emitting element 3. In the display device 20, layers included in the light-emitting element 3 are stacked on top of another above the array substrate 2. The TFT of the array substrate 2 and the light-emitting element 3 are electrically connected together.

The light-emitting element 3 includes: an anode 4 (a first electrode); a hole transport layer 5 (a first charge transport layer); a first light-emitting layer 6a; a first intermediate layer FL; a second light-emitting layer 6b; an electron transport layer 8 (a second charge transport layer); and a cathode 9 (a second electrode). The light-emitting element 3 can be formed to include the anode 4, the hole transport layer 5, the first light-emitting layer 6a, the first intermediate layer FL, the second light-emitting layer 6b, the electron transport layer 8, and the cathode 9, all of which are stacked on top of another in the stated order from below above the array substrate 2.

### Anode

The anode 4 is formed above the array substrate 2, and electrically connected to the TFT provided to the array substrate 2. The anode 4 is formed of a conductive material. Specifically, the anode 4 can be formed of a metal and a transparent conductive film stacked on top of another. The metal, functioning as a reflective layer, contains Al, Cu, Au, or Ag, each of which is highly reflective to light. The transparent conductive film, functioning as a transparent electrode, contains indium tin oxide, indium zinc oxide, zinc oxide, aluminum-doped zinc oxide, or boron-doped zinc oxide, each of which is transparent to light. The anode 4 can be formed above the array substrate 2, using such a technique as, for example, sputtering or vapor deposition.

### Hole Transport Layer

The hole transport layer 5 transports holes, which are injected from the anode 4, to the first light-emitting layer 6a. The hole transport layer 5 is formed above, and electrically connected to, the anode 4. The hole transport layer 5 may be formed of, for example, a material containing an inorganic oxide semiconductor such as NiO or MgNiO. Other than the above inorganic oxide semiconductor materials, the hole transport layer 5 can be formed also of an organic material such as a conductive polymer, or of a mixture of an organic material and an inorganic material.

However, as to the display device 20 according to the embodiment, the hole transport layer 5 is formed of an inorganic material such as an inorganic oxide semiconductor material in view of reliability of the light-emitting element 3. Note that the reliability of the light-emitting element 3 here means whether the light-emitting element 3 can emit light with a constant luminance for a long time. The reliability of the light-emitting element 3 can be evaluated in the form of, for example, time series variations in the luminance of the light emitted from the light-emitting element 3.

Note that the hole transport layer 5 can be formed by, for example, such a technique as sputtering, vapor deposition, spin coating, or ink-jet printing.

### First Light-Emitting Layer and Second Light-Emitting Layer

The first light-emitting layer 6a and the second light-emitting layer 6b are provided between the anode 4 and the cathode 9: more specifically, between the hole transport layer 5 and the electron transport layer 8. The first light-emitting layer 6a contains a plurality of first quantum dots Q1. The second light-emitting layer 6b contains a plurality of second quantum dots Q2. The first light-emitting layer 6a contains a first inorganic matrix material X1 filling spaces between the plurality of first quantum dots Q1. The second light-emitting layer 6b contains a second inorganic matrix material X2 filling spaces between the plurality of second quantum dots Q2.

Hereinafter, the first quantum dots Q1 and the second quantum dots Q2 may be collectively referred to as quantum dots Q. Each of the first light-emitting layer 6a and the second light-emitting layer 6b may contain one or more layers formed of the quantum dots Q and stacked on top of another.

Each of the quantum dots Q may be a particle having a maximum width smaller than, or equal to, 100 nm. The quantum dot Q may be spherical or non-spherical. The shape of the quantum dot Q shall not be limited to a spherical three-dimensional shape (with a circular cross-section) as long as the maximum width is smaller than, or equal to, 100 nm. For example, the quantum dot may have a polygonal cross-section, a bar-like three dimensional shape, a branch-like three dimensional shape, or a three dimensional shape having asperities on the surface. Alternatively, the quantum dot may have a combination of those shapes. The quantum dots Q may be formed of a semiconductor material. This semiconductor material may have a certain bandgap, and may be a material that produces electroluminescence. The electroluminescence may have a wavelength region of any of a red gamut, a green gamut, and a blue gamut.

The first quantum dots Q1 of the first light-emitting layer 6a and the second quantum dots Q2 of the second light-emitting layer 6b may be the same quantum dots. Here, the same quantum dots are quantum dots to be used for light-emitting layers included in the display device 20 and forming subpixels in the same color. That is, the light-emitting layer containing the same quantum dots shall not be limited only to a light-emitting layer containing quantum dots that are made of completely the same material, formed in completely the same composition, and sized in completely the same average particle diameter. The light-emitting layer contains quantum dots whose composition and particle diameter are deemed capable of forming subpixels in the same color. The same color among the subpixels is the same color in a sense that the color belongs to any one of a plurality of such primary colors as red, green, and blue constituting a display image. Hence, the same color among the subpixels may be substantially the same as far as the color is visible to human eyes. The peaks of the wavelengths in the light do not have to be completely the same in a strict sense. For example, if two peaks are detected in spectra of emission wavelengths in light emitted from two kinds of quantum dots, and the peak wavelengths are within a range of wavelengths in the same color; that is, 430 to 500 nm for blue, 500 to 570 nm for green, and 610 to 780 nm for red, the quantum dots are determined to be the same. Furthermore, as a matter of course, the quantum dots are determined to be the same if two peaks are not detected.

The quantum dots Q are a light-emitting material that emits light by recombination of holes at a valence band level and electrons at a conduction band level. The light emitted from the quantum dots Q has a narrow spectrum because of the quantum confinement effect. Hence, relatively deep chromaticity can be obtained for the emitted light.

The quantum dots Q may be selected from the group consisting of a II-VI semiconductor compound, a III-V semiconductor compound, and a IV semiconductor compound. Note that the II-VI semiconductor compound can be selected from, for example, MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe. Furthermore, the III-V semiconductor compound can be selected from, for example, GaAs, GaP, GaN, InN, InAs, InP, and InSb. Moreover, the IV semiconductor compound can be selected from, for example, Si and Ge. Note that the II-VI semiconductor compound means a compound containing a group II element and a group VI element. The III-V semiconductor compound means a compound containing a group III element and a group V element. The IV semiconductor compound means a compound containing a group IV element. In addition, the group II element means either a group 2 element or a group 12 element. The group III element means either a group 3 element or a group 13 element. The group IV element means either a group 4 element or a group 14 element. The group V element means either a group 5 element or a group 15 element. The group VI element means either a group 6 element or a group 16 element. Here, the group numbers in Roman numbers are denoted by the former IUPAC notation or the former CAS notation. The group numbers in Arabic numbers are denoted by the current IUPAC notation.

Furthermore, each of the quantum dots Q may be a semiconductor nanoparticle having a core-shell structure such as CdSe/Cds, CdSe/ZnS, InP/ZnS, and ZnSe/ZnS. Moreover, the shell may have an outer periphery coordinated with ligands formed of either an inorganic substance or an organic substance. The ligands may be used to deactivate defects on a surface of the shell and to improve dispersibility of the quantum dots in a solvent to be applied.

In the light-emitting element 3 according to the embodiment, the holes and the electrons recombine at an interface mainly between the first light-emitting layer 6a and the first intermediate layer FL, or at an interface between the second light-emitting layer 6b and the first intermediate layer FL. Furthermore, the light is emitted mainly in a range of approximately 5 nm from the interface between the first intermediate layer FL and the first light-emitting layer 6a and from the interface between the first intermediate layer FL and the second light-emitting layer 6b. Hence, a distance of more than 5 nm is kept: from the interface between the first light-emitting layer 6a and the first intermediate layer FL to the hole transport layer 5; and from the interface between the second light-emitting layer 6b and the first intermediate layer FL to the electron transport layer 8. Such a feature successfully reduces occurrence of quenching.

Thus, each of the first light-emitting layer 6a and the second light-emitting layer 6b has a thickness of preferably more than 5 nm. Moreover, in order to further reduce occurrence of quenching, each of the first light-emitting layer 6a and the second light-emitting layer 6b has a thickness of 10 nm or more, and, more preferably, 20 nm or more. Whereas, if the first light-emitting layer 6a and the second light-emitting layer 6b are excessively thick, an electrical resistance of both of the layers increases. As a result, a voltage to be applied between the anode 4 and the cathode 9 inevitably increases. Hence, in accordance with the magnitude of a drive voltage to be applied to the display device 20 when the display device 20 is used for, for example, a display, each of the first light-emitting layer 6a and the second light-emitting layer 6b has a thickness of preferably 40 nm or less. Furthermore, in view of reducing the drive voltage, each of the first light-emitting layer 6a and the second light-emitting layer 6b has a thickness of preferably 30 nm or less, more preferably 25 nm or less, still more preferably 20 nm or less, still more preferably 15nm or less, still more preferably 10nm or less, and still more preferably and 5nm or less.

Moreover, each of the first light-emitting layer 6a and the second light-emitting layer 6b has a thickness ranging between more than 5 nm and 40 nm or less, more preferably between 10 nm or more and 40 nm or less, and still more preferably between 20 nm or more and 40 nm or less. In addition, the thickness of each of the first light-emitting layer 6a and the second light-emitting layer 6b described above is set to the above numerical values for a single layer, so that the advantageous effects are exhibited for the single layer. The thickness can be individually set for each of the layers. Note that the first light-emitting layer 6a and the second light-emitting layer 6b are preferably approximately the same in thickness.

### First Intermediate Layer

The first intermediate layer FL is formed of a material higher in ionization potential, and lower in electron affinity, than the first light-emitting layer 6a and the second light-emitting layer 6b. That is, the first intermediate layer FL is formed of a material that serves as an energy barrier against both the electrons and the holes. The first intermediate layer FL preferably reduces conduction of the electrons and the holes. Furthermore, the first intermediate layer FL is preferably formed of a material that either reduces or prevents occurrence of quenching. The reduction in the conduction of the electrons and the holes means that, for example, as described above, the first intermediate layer FL is higher in ionization potential, or lower in electron affinity, than the first light-emitting layer 6a and the second light-emitting layer 6b, such that an energy barrier is generated to block the injection of the charges from either the first light-emitting layer 6a or the second light-emitting layer 6b to the first intermediate layer FL. Furthermore, for example, the first intermediate layer FL is formed lower either in carrier mobility or in carrier concentration than the first light-emitting layer 6a and the second light-emitting layer 6b, so as to have higher resistivity. The first intermediate layer can be formed either of an organic material or of a mixture of an organic material and an inorganic material. However, as to the display device 20 according to the embodiment, the first intermediate layer FL is formed of an inorganic material such as an inorganic oxide semiconductor material from the viewpoint of reliability of the light-emitting element 3.

Specifically, the first intermediate layer FL contains at least one selected from the group consisting of a metal oxide, a metal halide, and a metal sulfide. This metal oxide preferably contains at least one selected from the group consisting of Al₂O₃, SiO₂, MgO, ZrO₂, HfO₂, Cr₂O₃, Ga₂O₃, and Ta₂O₅. Furthermore, this metal halide preferably contains at least one selected from the group consisting of LiF, BaF₂, CaF₂, MgF₂, NaF, NaCl, CdF₂, CdCl₂, CdBr₂, CdI₂, ZnF₂, ZnCl₂, ZnBr₂, and ZnI₂. Moreover, this metal sulfide preferably contains at least one selected from the group consisting of ZnS, ZnMgS, ZnMgS₂, and MgS.

As can be seen, the first intermediate layer FL contains at least one selected from the group consisting of a metal oxide, a metal halide, and a metal sulfide. That is why the first intermediate layer FL is relatively stable against oxygen and moisture, and is less likely to deteriorate. As a result, the light-emitting element 3 can achieve high reliability. Furthermore, the first intermediate layer FL is higher in bandgap than the first light-emitting layer 6a and the second light-emitting layer 6b, which will be described in detail later. Hence, the light-emitting element 3 reduces conduction of the electrons and the holes, thereby successfully maintaining either a carrier balance between the holes and the electrons that recombine in the first light-emitting layer 6a, or a carrier balance between the holes and the electrons that recombine in the second light-emitting layer 6b.

The first intermediate layer FL has a thickness of preferably 0.5 nm or more in order to obtain an advantageous effect of reducing conduction of the electrons and the holes. Furthermore, the thicker the first intermediate layer FL is, the greater the electrical resistance is between the anode 4 and the cathode 9. Hence, in accordance with the magnitude of a drive voltage to be applied to the display device 20 when the display device 20 is used for, for example, a display, an upper limit can be determined of the thickness of the first intermediate layer FL. For example, the thickness of the first intermediate layer FL may have an upper limit of 20 nm or less. In view of reducing the drive voltage, the thickness is preferably smaller: 15 nm or less, more preferably 10 nm or less, and still more preferably 5 nm or less.

Here, the thickness of the first intermediate layer FL means a maximum thickness of any given cross-section observed when the first intermediate layer FL is cut in a thickness direction. The thickness of the first intermediate layer FL can be measured when a cross-section of the first intermediate layer FL is observed with such a device as a scanning electron microscope (SEM) or a transmission electron microscope (TEM).

Note that the first intermediate layer FL is not necessarily provided over an entire region in which the first light-emitting layer 6a and the second light-emitting layer 6b overlap with each other. The first intermediate layer FL is not necessarily provided over the entire surface of each of the light-emitting layers. The first intermediate layer FL includes a layer formed at least in a portion of a region in which the first light-emitting layer 6a and the second light-emitting layer 6b overlap with each other. Hence, even if the first intermediate layer FL is provided, a portion may be found with no first intermediate layer FL interposed between the first light-emitting layer 6a and the second light-emitting layer 6b. In the portion, the first light-emitting layer 6a and the second light-emitting layer 6b may face each other without the intermediate layer.

Specifically, the first intermediate layer FL may be a plurality of layers shaped into islands and provided between the first light-emitting layer 6a and the second light-emitting layer 6b. Furthermore, the first intermediate layer FL may have, for example, a plurality of through holes formed to penetrate the first intermediate layer FL in the thickness direction.

In any given cross-section of the first intermediate layer FL in the thickness direction, the intermediate layer preferably covers 10% or more, more preferably 30% or more, still more preferably 50% or more, still more preferably 70% or more, still more preferably 90% or more, and most preferably 100% of the surface of either the first light-emitting layer 6a or the second light-emitting layer 6b. Note that the statement, “covering 100% of the surface” means that intermediate layer has a portion continuously covering a width of 1 μm in a direction perpendicular to the thickness direction. That is, the above percentage figures can be sufficiently met when the width is measured within a range of 1 μm in the direction perpendicular to the thickness direction of the intermediate layer, and the measured figure is within the percentage figures.

Furthermore, the first intermediate layer FL does not have to have a substantially uniform thickness, and may have unevenness in thickness such as asperities.

### Electron Transport Layer

The electron transport layer 8 is provided above the second light-emitting layer 6b. The electron transport layer 8 transports the electrons, which are injected from the cathode 9, to the second light-emitting layer 6b. The electron transport layer 8 can be formed of, for example, a material containing an inorganic semiconductor in view of reliability. The electron transport layer 8 may contain at least one selected from the group consisting of, for example, ZnO, ZnMgO, TiO₂, Ta₂O₃, SnO₂, and SrTiO₃.

The hole transport layer 5, the first intermediate layer FL, and the electron transport layer 8 may be formed to include nanoparticles, crystals, polycrystals, or amorphous materials.

### Cathode

The cathode 9 is formed above the electron transport layer 8, and electrically connected to the electron transport layer 8. The cathode 9 is formed of a conductive material. The cathode 9 can be formed of, for example, a metal formed into a thin film transparent to light, a metal formed into nanoparticles, or a transparent electrode. Examples of the metal forming the cathode 9 include metals such as Al, Cu, Au, and Ag. Examples of the transparent electrode forming the cathode 9 include indium tin oxide, indium zinc oxide, zinc oxide, aluminum-doped zinc oxide, and boron-doped zinc oxide. The cathode 9 can be formed on the electron transport layer 8 by, for example, sputtering, vapor deposition, or spin coating.

In the display device 20 having the above-described configuration, the holes (the arrow h⁺ in FIG. 1) injected from the anode 4 are transported through the hole transport layer 5 into the first light-emitting layer 6a. Furthermore, the electrons (the arrow e⁻ in FIG. 1) injected from the cathode 9 are transported through the electron transport layer 8 into the second light-emitting layer 6b. Then, the holes transported to the first light-emitting layer 6a and electrons, which are included in the electrons transported to the second light-emitting layer 6b and are injected into the first light-emitting layer 6a beyond the first intermediate layer FL, recombine in the quantum dots Q, thereby generating excitons. Alternatively, the electrons transported to the second light-emitting layer 6b and holes, which are included in the holes transported to the first light-emitting layer 6a and are injected into the second light-emitting layer 6b beyond the first intermediate layer FL, recombine in the quantum dots Q, thereby generating excitons. Then, the excitons return from the excited state to the ground state, and thus the quantum dots Q emit light.

Note that FIG. 1 illustrates an example of a top-emission display device 20 that releases light, which is emitted from at least one of the first light-emitting layer 6a or the second light-emitting layer 6b, across from the array substrate 2 (from the top in FIG. 1). However, the display device 20 may also be a bottom-emission display device that releases light from the array substrate 2 (from the bottom in FIG. 1). If the display device 20 is a bottom-emission display device, the cathode 9 is a reflective electrode and the anode 4 is a transparent electrode.

Furthermore, the display device 20 according to a first embodiment includes the anode 4, the hole transport layer 5, the first light-emitting layer 6a, the first intermediate layer FL, the second light-emitting layer 6b, the electron transport layer 8, and the cathode 9, all of which are stacked on top of another in the stated order from below above the array substrate 2. However, the display device 20 may be an inverted display device; that is, the display device 20 may include the cathode 9, the electron transport layer 8, the second light-emitting layer 6b, the first intermediate layer FL, the first light-emitting layer 6a, the hole transport layer 5, and the anode 4, all of which are stacked on top of another in the stated order from below above the array substrate 2.

As can be seen, as to the display device 20 according to the embodiment, the hole transport layer 5 is formed of an inorganic material such as an inorganic oxide semiconductor material in view of reliability of the light-emitting element 3. Hence, when the hole transport layer 5 is formed of an inorganic oxide semiconductor material, a light-emitting element without the first intermediate layer FL has a problem as follows.

The holes transported from the hole transport layer to the light-emitting layer are likely to be smaller in amount than the electrons transported from the electron transport layer to the light-emitting layer. Thus, excitons are likely to be generated, and the light is likely to be emitted, near an interface between the hole transport layer and the light-emitting layer. However, because of a —OH group contained in an oxide forming the hole transport layer, or of a strong electric field generated by a dipole of a dangling bond, the excitons are separated into the electrons and the holes near the interface between the hole transport layer and the light-emitting layer. That is why quenching is likely to occur.

Hence, in the display device 20 according to this embodiment, the first intermediate layer FL is provided between the first light-emitting layer 6a and the second light-emitting layer 6b. Thus, the light is emitted mainly either: at or near the interface between the first light-emitting layer 6a and the first intermediate layer FL; or at or near the interface between the second light-emitting layer 6b and the first intermediate layer FL so that the light-emitting region is distant from the hole transport layer 5. Such a feature successfully reduces occurrence of quenching.

Described next with reference to FIG. 2 will be a relationship of energy between the first light-emitting layer 6a and the first intermediate layer FL and between the second light-emitting layer 6b and the first intermediate layer FL. FIG. 2 illustrates a state in which the hole transport layer 5, the first light-emitting layer 6a, the second light-emitting layer 6b, the first intermediate layer FL, and the electron transport layer 8 are isolated from one another.

Note that, as illustrated in FIG. 2, the anode 4, the hole transport layer 5, the first light-emitting layer 6a, the first intermediate layer FL, the second light-emitting layer 6b, the electron transport layer 8, and the cathode 9 are arranged from left to right. In the drawings of the Description, the hole transport layer 5 and the electron transport layer 8 are respectively denoted as an HTL and an ETL.

Furthermore, in the energy band diagrams, the anode 4 and the cathode 9 are represented by work functions. Each of the hole transport layer 5, the first light-emitting layer 6a, the second light-emitting layer 6b, the first intermediate layer FL, and the electron transport layer 8 has a lower end corresponding to a valence band maximum (VBM) and representing an ionization potential of each of the layers with reference to the vacuum level. Note that the VBM corresponds to the highest occupied molecular orbital (HOMO) in the case of a molecule.

Furthermore, each of the hole transport layer 5, the first light-emitting layer 6a, the second light-emitting layer 6b, the first intermediate layer FL, and the electron transport layer 8 has an upper end corresponding to a conduction band minimum (CBM) and representing an electron affinity of each of the layers with reference to the vacuum level. Note that the CBM corresponds to the lowest unoccupied molecular orbital (LUMO) in the case of a molecule. Hereinafter, the ionization potential means a difference between the vacuum level and the energy level of the VBM or HOMO, and the electron affinity means the difference between the vacuum level and the energy level of the CBM or LUMO.

As described above, the first light-emitting layer 6a and the second light-emitting layer 6b contain the same quantum dots. The same quantum dots emit light whose colors are within the wavelength ranges of blue, green, and red. Here, the quantum dots are made of the same material, formed in the same composition, and sized in the same average particle diameter. Hence, the first quantum dots Q1 of the first light-emitting layer 6a and the second quantum dots Q2 of the second light-emitting layer 6b are the same in ionization potential and electron affinity as illustrated in FIG. 2.

Furthermore, the first inorganic matrix material X1 of the first light-emitting layer 6a and the second inorganic matrix material X2 of the second light-emitting layer 6b are made of the same material and formed in the same composition. Hence, as illustrated in FIG. 2, the first inorganic matrix material X1 and the second inorganic matrix material X2 are the same in ionization potential and electron affinity.

Whereas, the first intermediate layer FL sandwiched between the first light-emitting layer 6a and the second light-emitting layer 6b is higher in ionization potential, and lower in electron affinity, than the first light-emitting layer 6a and the second light-emitting layer 6b. That is, the first intermediate layer FL serves as an energy barrier for the holes to be conducted from the first light-emitting layer 6a to the second light-emitting layer 6b and for the electrons to be conducted from the second light-emitting layer 6b to the first light-emitting layer 6a. Hence, the holes are likely to be accumulated near the interface between the first intermediate layer FL and the first light-emitting layer 6a, and the electrons are likely to be accumulated near the interface between the first intermediate layer FL and the second light-emitting layer 6b. Then, among the holes accumulated in the first light-emitting layer 6a, holes moving to the second light-emitting layer 6b beyond the first intermediate layer FL recombine with the electrons at or near the interface between the first intermediate layer FL and the second light-emitting layer 6b. As a result, the light is emitted. On the other hand, among the electrons accumulated in the second light-emitting layer 6b, electrons moving to the first light-emitting layer 6a beyond the first intermediate layer FL recombine with the holes at or near the interface between the first intermediate layer FL and the first light-emitting layer 6a. As a result, the light is emitted.

As can be seen, in the light-emitting element 3 according to the embodiment, the thickness of each of the first light-emitting layer 6a and the second light-emitting layer 6b is more than 5 nm, preferably 10 nm or more, and more preferably 20 nm or more. Hence, a distance of more than 5 nm can be set from a center of light, emitted at least from the first light-emitting layer 6a, to the hole transport layer 5. Furthermore, a distance of more than 5 nm can be set from a center of light, emitted at least from the second light-emitting layer 6b, to the electron transport layer 8. Here, the light-emitting element 3 emits light mainly in a range of approximately 5 nm from the interface between the first intermediate layer FL and the first light-emitting layer 6a and in a range of approximately 5 nm from the interface between the first intermediate layer FL and the second light-emitting layer 6b.

Hence, in the light-emitting element 3, the light-emitting region from which the light is emitted can be physically separated from either the hole transport layer 5 or the electron transport layer 8 both of which cause quenching. Such a feature successfully reduces occurrence of quenching and increases luminance efficiency.

When the display device 20 operates for a long period of time, a decrease could be observed either in the amount of holes injected into the first light-emitting layer 6a or in the amount of electrons injected into the second light-emitting layer 6b. Here, when the amount of the injected holes or the injected electrons decreases and the carrier balance between the holes and the electrons deteriorates, Auger recombination occurs. The problem is that Auger recombination decreases luminance and light emission efficiency.

However, the light-emitting element 3 according to the embodiment includes the first intermediate layer FL. Hence, even if a decrease is observed in the amount of charges injected into the light-emitting layer, the first intermediate layer FL successfully reduces occurrence of Auger recombination. For example, assume a case where a decrease is observed in the amount of holes injected from the hole transport layer 5 to the first light-emitting layer 6a. In this case, the light-emitting element 3 according to the embodiment can reduce the injection of electrons into the first light-emitting layer 6a with the first intermediate layer FL. Hence, the first light-emitting layer 6a can reduce deterioration of the carrier balance between the holes and the electrons and emit light stably.

Whereas, in the second light-emitting layer 6b, the first intermediate layer FL further reduces the amount of holes injected into the second light-emitting layer 6b, and the holes and the electrons are kept from recombining together. Thus, the second light-emitting layer 6b does not emit light. Furthermore, in the second light-emitting layer 6b, the holes and the electrons are kept from recombining together such that no light is emitted. As a result, the Auger recombination does not occur.

Although not shown in FIG. 1 or FIG. 2, the light-emitting element 3 may further include a hole injection layer between the anode 4 and the hole transport layer 5. Moreover, the light-emitting element 3 may further include an electron injection layer between the cathode 9 and the electron transport layer 8.

### Inorganic Matrix Material

The first light-emitting layer 6a contains the first inorganic matrix material X1 filling spaces between the plurality of first quantum dots Q1 (i.e., containing the plurality of first quantum dots Q1). The second light-emitting layer 6b contains the second inorganic matrix material X2 filling spaces between the plurality of second quantum dots Q2 (i.e., containing the plurality of quantum dots Q2). Hereinafter, the first inorganic matrix material X1 and the second inorganic matrix material X2 may be collectively referred to as an inorganic matrix material X.

The inorganic matrix material X means a member formed of an inorganic substance (e.g., an inorganic semiconductor) and containing and holding other substances. The inorganic matrix material X can be also referred to as a base material, a matrix, or a filler. The inorganic matrix material X may be a solid at room temperature. The inorganic matrix material X may be a member containing and holding the plurality of quantum dots Q. The inorganic matrix material X may be a feature of the light-emitting layers (6a and 6b) containing the plurality of quantum dots Q.

As illustrated in FIG. 1, the inorganic matrix material X may be filled in the light-emitting layers (6a and 6b). The inorganic matrix material X may fill a region (a space) other than the plurality of quantum dots Q in the light-emitting layers (6a, 6b).

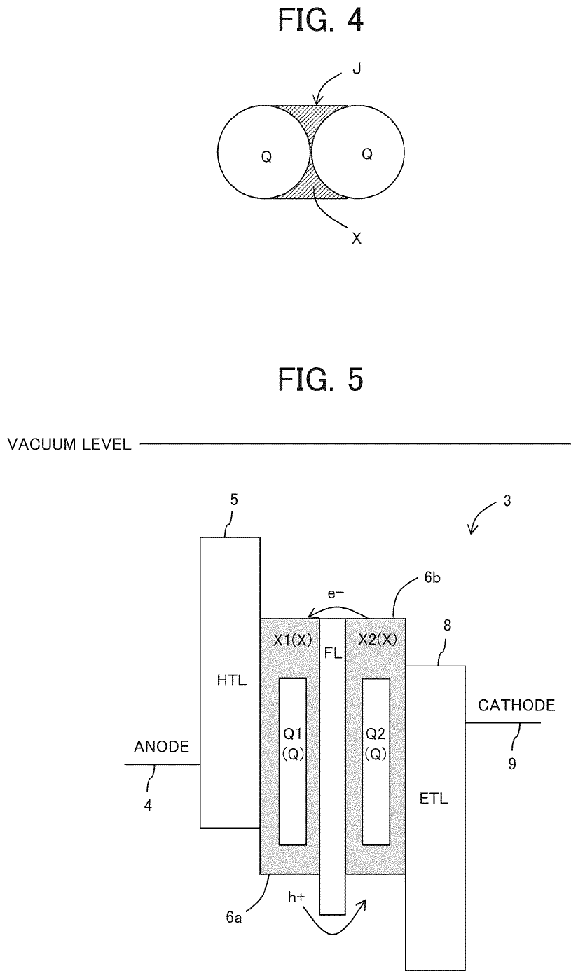

The inorganic matrix material X may be filled between the plurality of quantum dots Q. When the inorganic matrix material X is filled between the plurality of quantum dots Q, it means that the inorganic matrix material X fills a region between neighboring two quantum dots Q (hereinafter referred to as “region”). The inorganic matrix material X fills a space at least between neighboring two quantum dots Q, and achieves a desired advantageous effect in the region where the inorganic matrix material fills at least between the two quantum dots. FIGS. 3 and 4 are schematic cross-sectional views of an example of how the inorganic matrix material is formed. As illustrated in FIGS. 3 and 4, the inorganic matrix material X fills a region (a space) J between neighboring two quantum dots Q. The inorganic matrix material X is filled in the region J. The region J may be, in a cross-section of a light-emitting layer (6a, 6b), a region surrounded with: two straight lines (i.e., common outer tangent lines) in contact with the outer peripheries of the neighboring two quantum dots Q; and opposing outer peripheries of the neighboring two quantum dots Q. Note that, as illustrated in FIG. 4, the region J can exist even if the neighboring two quantum dots are close to each other. In addition, the inorganic matrix material X fills the region J.

The inorganic matrix material X may fill a region (a space) other than a quantum dot group in the light-emitting layer (6a, 6b). Here, three or more quantum dots Q are collectively referred to as a quantum dot group. The inorganic matrix material X may fill a region (a space) other than the plurality of quantum dots Q in the light-emitting layer (6a, 6b).

The light-emitting layer (6a, 6b) has an outer edge (an upper surface and a lower surface) covered with the inorganic matrix material X. Furthermore, the outer edge of the light-emitting layer (6a, 6b) may be formed of the inorganic matrix material X, and the quantum dots Q may be positioned away from the outer edge. The outer edge of the light-emitting layer (6a, 6b) does not have to be formed of the inorganic matrix material X alone. The quantum dots Q may be partially exposed from the inorganic matrix material X. The inorganic matrix material X in the light-emitting layer (6a, 6b) may be a portion except for the plurality of quantum dots Q.

The inorganic matrix material X may contain the plurality of quantum dots Q. The inorganic matrix material X may be formed to fill spaces formed between the plurality of quantum dots Q. The plurality of quantum dots Q may be buried at intervals in the inorganic matrix material X. The inorganic matrix material X may be either partially or completely filled between the plurality of quantum dots Q.

The inorganic matrix material X may include a continuous film having an area of 1000 nm² or more in a planer direction perpendicular to the thickness direction. The continuous film means a film whose single plane is not separated with a material other than the material forming the continuous film.

The inorganic matrix material X may be formed of the same material as the material of the shell included in each of the plurality of quantum dots Q. In this case, an average distance between neighboring cores (an inter-core distance) may be 3 nm or more, and may be 5 nm or more. Alternatively, the average distance between the neighboring cores may be 0.5 times as long as, or longer than, an average core diameter. The inter-core distance is an average distance between neighboring cores in a space including 20 cores. The inter-core distance may be kept longer than a distance between shells in contact with each other. The average core diameter is an average of core diameters of 20 cores when a space including the 20 cores is observed in cross-section. Each of the core diameters can be interpreted as a diameter of a circle whose area is as large as an area of the core observed in cross-section.

In the light-emitting layer (6a, 6b), the inorganic matrix material X may have a concentration of 0.1% or more and 79.0% or less. This concentration may be measured from, for example, a rate of the area in image processing when the cross-section is observed. If the quantum dots Q have a core-shell structure, the shells may have a concentration of 0.1% or more and 39% or less. If the shells and the inorganic matrix material X are formed of the same material (formed in the same composition), and the shells and the inorganic matrix material X cannot be distinguished from each other, a concentration of 0.1% or more and 99.9% or less may be observed of the region including the shells and the inorganic matrix material X combined. As can be seen, if the shells and the inorganic matrix material X cannot be distinguished from each other, the shells may be a portion of the inorganic matrix material X.

The light-emitting layer (6a, 6b) may be formed of the plurality of quantum dots Q and the inorganic matrix material X. When the light-emitting layer (6a, 6b) is analyzed, strength of carbon detected in a chain structure may be equal to noise or less.

The material forming the inorganic matrix material X is desirably wider in bandgap than the material (e.g., the core material) of the quantum dots Q. The material to be used for forming the inorganic matrix material X may be either a semiconductor or an insulator. Examples of the material forming the inorganic matrix material X include a metal sulfide and/or a metal oxide. Example of the metal sulfide may include zinc sulfide (ZnS), zinc magnesium sulfide (ZnMgS, ZnMgS₂), gallium sulfide (GaS, Ga₂S₃), zinc tellurium sulfide (ZnTeS), magnesium sulfide (MgS), zinc gallium sulfide (ZnGa₂S₄), and magnesium gallium sulfide (MgGa₂S₄). Examples of the metal oxide may include zinc oxide (ZnO), titanium oxide (TiO₂), tin oxide (SnO₂), tungsten oxide (WO₃), and zirconium oxides (ZrO₂). Note that the chemical formulas denoted in parentheses after the compound names are typical examples. Furthermore, a composition ratio described in a chemical formula is preferably in stoichiometry in which a composition of the actual compound is the same as the chemical formula. However, the composition ratio does not have to be in stoichiometry.

The structure of the inorganic matrix material X may as well be seen to be the above one when the cross-section of the light-emitting layer (6a, 6b) is observed at a width of approximately 100 nm. The structure does not have to be observed throughout the light-emitting layer (6a, 6b). The inorganic matrix material X may contain a substance different from the main material (e.g., an inorganic substance such as an inorganic semiconductor) as, for example, an additive.

For example, the light-emitting layer (6a, 6b) can be made inorganic when organic ligands are removed from the inorganic matrix material X (e.g., a semiconductor material), and the light-emitting quantum dots Q are embedded in the inorganic matrix material X.

The light-emitting element 3 illustrated in FIGS. 1 and 2 includes: the first light-emitting layer 6a provided between the first electrode 4 and the second electrode 9, and containing the plurality of first quantum dots Q1 and the first inorganic matrix material X1 filling spaces between the plurality of first quantum dots Q1; the second light-emitting layer 6b provided between the second electrode 9 and the first light-emitting layer 6a, and containing the plurality of second quantum dots Q2 and the second inorganic matrix material X2 filling spaces between the plurality of quantum dots Q2, the second quantum dots Q2 emitting light in the same color as a color of light emitted from the plurality of quantum dots Q1; and the first intermediate layer FL provided between the first light-emitting layer 6a and the second light-emitting layer 6b.

The first quantum dots Q1 and the second quantum dots Q2 may have the same characteristic in emitting light (i.e., may be formed of the same material and in the same structure). The first inorganic matrix material X1 and the second inorganic matrix material X2 may be formed of the same material (i.e., may be formed in the same bandgap structure). The first inorganic matrix material X1 may contain the plurality of first quantum dots Q1. The second inorganic matrix material X2 may contain the plurality of second quantum dots Q2.

The inorganic matrix material X containing the plurality of quantum dots Q and filling the spaces between the plurality of quantum dots Q functions as a protective film. Such a feature successfully reduces an influence that the first light-emitting layer 6a has when the first intermediate layer FL and the second light-emitting layer 6b are formed, and prevents the first and second light-emitting layers 6a and 6b from deteriorating when the light-emitting element 3 is energized. A conventional light-emitting layer in which organic ligands are coordinated to quantum dots has a problem; that is, in a process after the light-emitting layer is formed and in the energization after the element is formed, such phenomena as desorption, denaturation, and decomposition of the organic ligands reduce light emission efficiency. However, this problem can be solved when the inorganic matrix material X is formed.

The inorganic matrix material X functions as a protective film of the quantum dots Q, which is advantageous because the first intermediate layer FL can be formed by sputtering.

Desirably, the inorganic matrix material X (X1, X2) is larger in bandgap than the quantum dots Q (Q1, Q2), and the bandgap of the quantum dots Q is positioned in the bandgap of the inorganic matrix material X. That is, preferably, the inorganic matrix material X is higher in ionization potential, and lower in electron affinity, than the quantum dots Q (Q1, Q2).

The first intermediate layer FL may be higher in ionization potential than the plurality of first quantum dots Q1, the first inorganic matrix material X1, the plurality of second quantum dots Q2, and the second inorganic matrix material X2. The first intermediate layer FL may be lower in electron affinity than the plurality of first quantum dots Q1, the first inorganic matrix material X1, the plurality of second quantum dots Q2, and the second inorganic matrix material X2.

The first intermediate layer FL in FIG. 2 is higher in ionization potential, and lower in electron affinity, than the inorganic matrix material X (X1, X2). Hence, the first intermediate layer FL serves as an energy barrier against both the electrons and the holes with respect to the inorganic matrix material X (X1, X2). Such a feature successfully reduces a reactive current that runs through the inorganic matrix material X as a carrier path (i.e., a reactive current that does not pass through the quantum dots). The inventors have found out that the inorganic matrix material X has a problem of transmitting carriers and generating a reactive current more readily than organic ligands, and that the first intermediate layer FL can significantly reduce the problem.

In the light-emitting element 3 illustrated in FIGS. 1 and 2, the first intermediate layer FL serves as an energy barrier against the electrons and the holes. As a result, the carriers are accumulated near the interface either between the first intermediate layer FL and the first light-emitting layer 6a or between the first intermediate layer FL and the second light-emitting layer 6b, such that the electrons and the holes are likely to recombine together (i.e., light is likely to be emitted) near the interface. The recombination (the light emission) region is away from the hole transport layer (the HTL) and the electron transport layer (the ETL). Such a feature successfully reduces occurrence of a quenching phenomenon in which energy of the excitons moves either to the HTL or to the ETL.

Each of the first and second light-emitting layers 6a and 6b may contain one or more layers formed of the plurality of quantum dots Q and stacked on top of another, and may have a thickness of 5 nm or more or of 20 nm or more and 40 nm or less. Preferably, the first light-emitting layer 6a and the second light-emitting layer 6b are approximately the same in thickness.

The first intermediate layer FL is desirably higher in ionization potential than the quantum dots Q (Q1, Q2). If the first intermediate layer FL is lower in ionization potential than the quantum dots Q, the holes are accumulated in the first intermediate layer FL and the recombination is likely to occur in the first intermediate layer FL in which no quantum dots are found.

The first intermediate layer FL is desirably lower in electron affinity than the quantum dots Q (Q1, Q2). If the first intermediate layer FL is higher in electron affinity than the quantum dots Q, the electrons are accumulated in the first intermediate layer FL and the recombination is likely to occur in the first intermediate layer FL in which no quantum dots are found.

In view of color purity of the light-emitting element 3, a difference in peak emission wavelength between the first and second light-emitting layers 6a and 6b is desirably small. Preferably, the difference is less than 10 nm.

The first inorganic matrix material X1 and the second inorganic matrix material X2 may contain a sulfide (e.g., zinc sulfide). The first inorganic matrix material X1 and the second inorganic matrix material X2 may contain a shell material (e.g., zinc sulfide) for the core-shell quantum dots Q.

The first intermediate layer FL contains at least one of a metal oxide, a halide, or a sulfide. If the first intermediate layer FL is formed of a sulfide semiconductor (e.g., ZnS, ZnMgS, ZnMgS₂, or MgS), the first intermediate layer FL has a thickness of preferably 5 nm or more and 10 to 20 nm. If the first intermediate layer FL is formed either of an insulating oxide or of a halide, the first intermediate layer FL has a thickness of preferably approximately 20 nm or less and 0.5 nm to 5 nm. This is because an excessively thick first intermediate layer FL will not transmit the carriers.

The first intermediate layer FL may contain a metal element (e.g., Zn) and a nonmetal element both contained in common in the first inorganic matrix material X1 and the second inorganic matrix material X2.

### Modification

FIG. 5 is an energy band diagram of another light-emitting element according to this embodiment. For convenience in description, FIG. 5 illustrates a state in which the hole transport layer 5, the first light-emitting layer 6a, the second light-emitting layer 6b, the first intermediate layer FL, and the electron transport layer 8 are isolated from one another.

In the light-emitting element 3 illustrated in FIG. 5, the first intermediate layer FL is higher in ionization potential than the first light-emitting layer 6a and the second light-emitting layer 6b. Furthermore, the first intermediate layer FL is higher, or equal, in electron affinity than, or to, the first light-emitting layer 6a and the second light-emitting layer 6b. Specifically, the first intermediate layer FL is higher, or equal, in electron affinity than, or to, any one of substances including the plurality of first quantum dots Q1, the first inorganic matrix material X1, the plurality of second quantum dots Q2, and the second inorganic matrix material X2.

In the light-emitting element 3, if the amount of holes injected into the first light-emitting layer 6a is excessively larger than the amount of electrons injected into the second light-emitting layer 6b, the first intermediate layer FL serving as an energy barrier can keep the holes from moving from the first light-emitting layer 6a to the second light-emitting layer 6b. Hence, in the structure of injecting the holes in an excessive amount, the light-emitting element 3 in FIG. 5 can maintain a carrier balance between the holes and the electrons that recombine in the second light-emitting layer 6b.

Note that examples of a material higher in ionization potential than the first light-emitting layer 6a and the second light-emitting layer 6b may include the metal oxide, the metal halide, and the metal sulfide described above, and may further include ZnO, ZnMgO, TiO₂, SnO₃, WO₃, MoO₃, V₂O₅, and ZnOS.

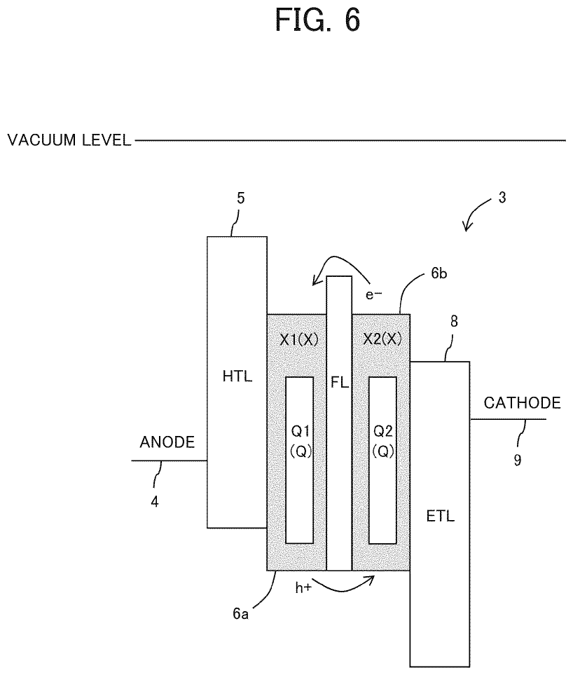

FIG. 6 is an energy band diagram of yet another light-emitting element according to this embodiment. In the light-emitting element 3 illustrated in FIG. 6, the first intermediate layer FL is lower in electron affinity than the first light-emitting layer 6a and the second light-emitting layer 6b. Furthermore, the first intermediate layer FL is lower, or equal, in ionization potential than, or to, the first light-emitting layer 6a and the second light-emitting layer 6b. That is, the first intermediate layer FL is lower, or equal, in ionization potential than, or to, any one of such substances as the plurality of first quantum dots Q1, the first inorganic matrix material X1, the plurality of second quantum dots Q2, and the second inorganic matrix material X2.

In the light-emitting element 3, if the amount of electrons injected into the second light-emitting layer 6b is excessively larger than the amount of holes injected into the first light-emitting layer 6a, the first intermediate layer FL serving as an energy barrier can keep the electrons from moving from the second light-emitting layer 6b to the first light-emitting layer 6a. Hence, in the structure of injecting the electrons in an excessive amount, the light-emitting element 3 in FIG. 6 can maintain a carrier balance between the holes and the electrons that recombine in the first light-emitting layer 6a.

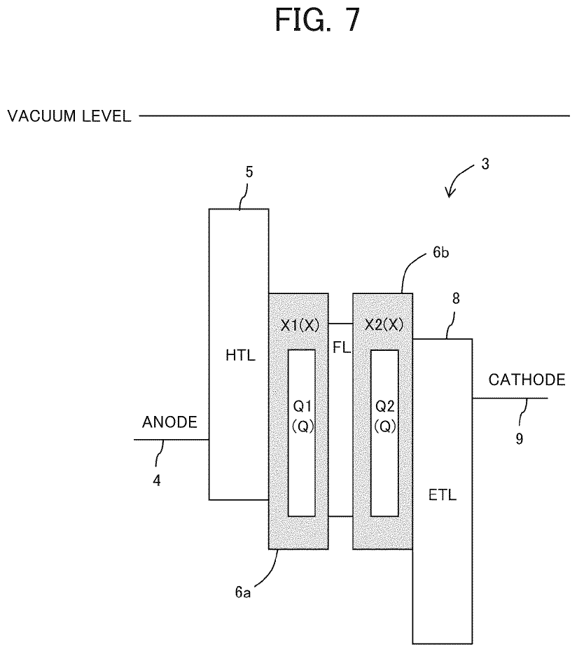

FIG. 7 is an energy band diagram of yet another light-emitting element according to this embodiment. The first intermediate layer FL is preferably larger in bandgap than the inorganic matrix material X. However, as illustrated in FIG. 7, even if the bandgap of the first intermediate layer FL is smaller than, or equal to, the bandgap of the inorganic matrix material X, the first intermediate layer FL can reduce quenching that occurs near either the hole transport layer 5 (the HTL) or the electron transport layer 8 (the ETL). A great distance between the first and second light-emitting layers 6a and 6b reduces carriers reaching near either the HTL or the ETL, thereby successfully reducing quenching. Furthermore, if the band profile is depressed in the first intermediate layer FL, carriers conducted through the inorganic matrix material X can be accumulated (trapped) in the first intermediate layer FL. Such a feature successfully reduces quenching that occurs near either the hole transport layer (the HTL) 5 or the electron transport layer (the ETL) 8.

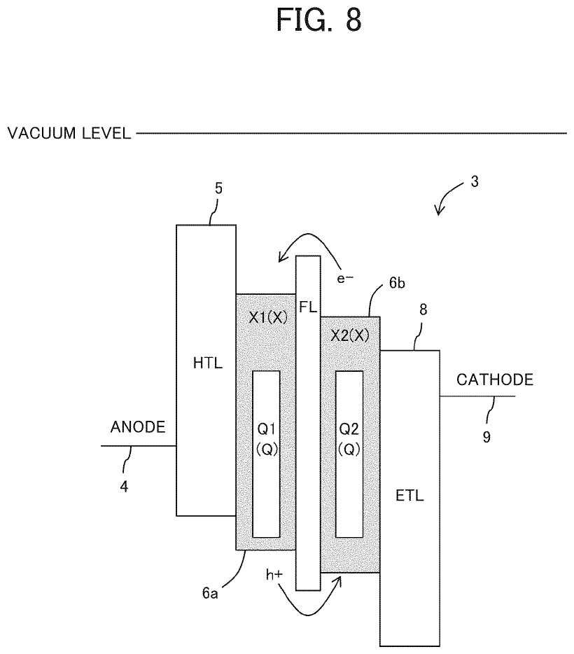

FIG. 8 is an energy band diagram of yet another light-emitting element according to this embodiment. As illustrated in FIG. 8, the first inorganic matrix material X1 may be lower in ionization potential and electron affinity than the second inorganic matrix material X2. For example, the first inorganic matrix material X1 may be ZnS and the second inorganic matrix material X2 may be ZnOS The first quantum dots Q1 and the second quantum dots Q2 may have the same characteristic in emitting light (i.e., may be formed of the same material and in the same structure).

In the case of FIG. 8, a barrier is formed against the holes to be injected from the first light-emitting layer 6a to the second inorganic matrix material X2, and a barrier is formed against the electrons to be injected from the second light-emitting layer 6b to the first inorganic matrix material X1. Hence, carriers (the electrons and the holes) that have traveled beyond the first intermediate layer FL are more likely to be injected into the quantum dots Q than into the inorganic matrix material X, and the reactive current passing through the inorganic matrix material X decreases. As a result, an effect of recombination (light emission) is observed more remarkably near the interface between either the first intermediate layer FL and the first light-emitting layer 6a or between the first intermediate layer FL and the second light-emitting layer 6b.

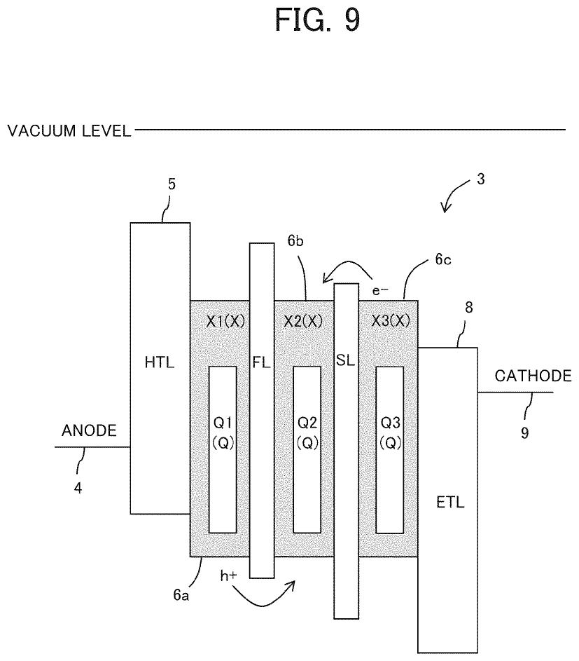

FIG. 9 is an energy band diagram of yet another light-emitting element according to this embodiment. For convenience in description, FIG. 9 illustrates a state in which the hole transport layer 5, the first light-emitting layer 6a, the second light-emitting layer 6b, a third light-emitting layer 6c, the first intermediate layer FL, a second intermediate layer SL, and the electron transport layer 8 are isolated from one another.

The light-emitting element 3 of FIG. 9 includes the third light-emitting layer 6c between the hole transport layer 5 and the electron transport layer 8, in addition to the first light-emitting layer 6a and the second light-emitting layer 6b. Furthermore, the second intermediate layer SL is included between the second light-emitting layer 6b and the third light-emitting layer 6c.

Specifically, the light-emitting element 3 includes: the third light-emitting layer 6c provided between the cathode 9 (the second electrode) and the second electrode 6b, and containing a plurality of third quantum dots Q3 and a third inorganic matrix material X3 filling spaces between the plurality of third quantum dots Q3, the third quantum dots Q3 emitting light in the same color as the color of the light emitted from the plurality of first quantum dots Q1; and the second intermediate layer SL provided between the second light-emitting layer 6b and the third light-emitting layer 6c. The first quantum dots Q1, the second quantum dots Q2, and the third quantum dots Q3 may have the same characteristic in emitting light (i.e., may be formed of the same material and in the same structure). The first inorganic matrix material X1, the second inorganic matrix material X2, and the third inorganic matrix material X3 may be formed of the same material (i.e., may be formed in the same bandgap structure). The third inorganic matrix material X3 may contain the plurality of third quantum dots Q3. Note that the display device including the light-emitting element of FIG. 9 has a configuration as follows. In FIG. 1, between the light-emitting layer 6b and the electron transport layer 8, the second intermediate layer SL (provided below) and the third light-emitting layer 6c (including the plurality of third quantum dots Q3 and the third inorganic matrix material X3) are sandwiched.

The first intermediate layer FL is lower in electron affinity than the first light-emitting layer 6a, the second light-emitting layer 6b, and the third light-emitting layer 6c. The second intermediate layer SL is higher in ionization potential than the first light-emitting layer 6a, the second light-emitting layer 6b, and the third light-emitting layer 6c. The first intermediate layer FL is lower in electron affinity and ionization potential than the second intermediate layer SL.

Hence, the first intermediate layer FL serves as an energy barrier against the electrons moving from the second light-emitting layer 6b to the first light-emitting layer 6a. Furthermore, the second intermediate layer SL serves as an energy barrier against the holes moving from the second light-emitting layer 6b to the third light-emitting layer 6c. Moreover, the first intermediate layer FL is lower in electron affinity and ionization potential than the second intermediate layer SL. As can be seen, the first intermediate layer FL is lower in electron affinity than the second intermediate layer SL. That is why the electrons are more likely to move from the third light-emitting layer 6c to the second light-emitting layer 6b than from the second light-emitting layer 6b to the first light-emitting layer 6a.

Furthermore, the first intermediate layer FL is lower in ionization potential than the second intermediate layer SL. That is why the holes are more likely to move from the second light-emitting layer 6b to the third light-emitting layer 6c than from the first light-emitting layer 6a to the second light-emitting layer 6b. As a result, the light-emitting element 3 in FIG. 9 can efficiently accumulate the electrons and the holes in the second light-emitting layer 6b.

Described below will be exemplary combinations of materials of the first intermediate layer FL and the second intermediate layer SL that can be used for the light-emitting element 3 of FIG. 9.

That is, the exemplary combinations include: a combination of MgNiO for the first intermediate layer FL and ZnMgO for the second intermediate layer SL; a combination of NiO for the first intermediate layer FL and ZnO for the second intermediate layer SL, a combination of MgO for the first intermediate layer FL and Al₂O₃ for the second intermediate layer SL, and a combination of ZnMgS for the first intermediate layer FL and ZnOS for the second intermediate layer SL. The combination of both materials; that is, a material forming the first intermediate layer FL and a material forming the second intermediate layer SL exemplified above, satisfies a relationship between the electron affinity and the ionization potential in each layer of the light-emitting element 3 illustrated in FIG. 9.

In the light-emitting element 3 illustrated in FIG. 9, the electrons and the holes are likely to be accumulated in the second light-emitting layer 6b. Then, the electrons and the holes recombine together mainly in the second light-emitting layer 6b. Hence, the electrons and the holes recombine together in the second light-emitting layer 6b positioned away from the hole transport layer 5 and the electron transport layer 8. Such a feature successfully reduces occurrence of quenching.

Furthermore, in the light-emitting element 3 of FIG. 9, the light is emitted mainly from the second light-emitting layer 6b. Note that the light of the second light-emitting layer 6b is emitted either at the first light-emitting layer 6a or at the third light-emitting layer 6c, depending on difference in mobility between the holes and the electrons. Thus, in the second light-emitting layer 6b, a center of the emitted light might be displaced toward either light-emitting layer.

Hence, in order to minimize the displacement of the center of the emitted light in the second light-emitting layer 6b, the second light-emitting layer 6b is formed preferably thinner than the first light-emitting layer 6a and the third light-emitting layer 6c.

In FIG. 9, the first intermediate layer FL provided between the first light-emitting layer 6a and the second light-emitting layer 6b is higher in ionization potential, and lower in electron affinity, than the plurality of first quantum dots Q1, the plurality of second quantum dots Q2, the plurality of third quantum dots Q3, the first inorganic matrix material X1, the second inorganic matrix material X2, and the third inorganic matrix material X3.

The second intermediate layer SL provided between the second light-emitting layer 6b and the third light-emitting layer 6c is higher in ionization potential, and lower in electron affinity, than the plurality of first quantum dots Q1, the plurality of second quantum dots Q2, the plurality of third quantum dots Q3, the first inorganic matrix material X1, the second inorganic matrix material X2, and the third inorganic matrix material X3. Such features successfully reduce a reactive current that runs through the inorganic matrix material X (X1, X2, and X3) as a carrier path.

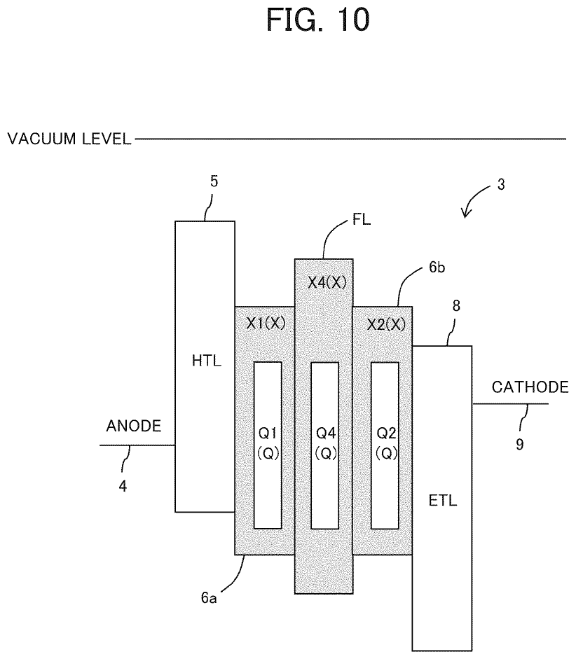

FIG. 10 is an energy band diagram of yet another light-emitting element according to this embodiment. In the light-emitting element 3 of FIG. 10, the first intermediate layer FL includes: a plurality of fourth quantum dots Q4 that emit light in the same color as the color of the light emitted from the plurality of the first quantum dots Q1; and a fourth inorganic matrix material X4 filling spaces between the fourth quantum dots Q4. The fourth inorganic matrix material X4 is higher in ionization potential, and lower in electron affinity, than the plurality of first quantum dots Q1, the plurality of second quantum dots Q2, the first inorganic matrix material X1, and the second inorganic matrix material X2. The first quantum dots Q1, the second quantum dots Q2, and the fourth quantum dots Q4 may have the same characteristic in emitting light (i.e., may be formed of the same material and in the same structure). The first inorganic matrix material X1 and the second inorganic matrix material X2 may be formed of the same material (i.e., may be formed in the same bandgap structure). The fourth inorganic matrix material X4 may contain the plurality of fourth quantum dots Q4. Note that the display device including the light-emitting element of FIG. 10 has a configuration as follows. In FIG. 1, the first intermediate layer FL contains the plurality of fourth quantum dots Q4 and the fourth inorganic matrix material X4.

In FIG. 10, the fourth inorganic matrix material X4 of the first intermediate layer FL serves as an energy barrier against both the electrons and the holes with respect to the first and second inorganic matrix materials X1 and X2. Such a feature successfully reduces a reactive current that runs through the inorganic matrix material X as a carrier path (i.e., a reactive current that does not pass through the quantum dots).

Whereas, the carriers are readily injected into the fourth quantum dots Q4 in the first intermediate layer FL, thereby increasing a chance of recombination in (light emission from) the fourth quantum dots Q4. The fourth quantum dots Q4 are away from the hole transport layer 5 and the electron transport layer 8. Such a feature successfully reduces occurrence of quenching.

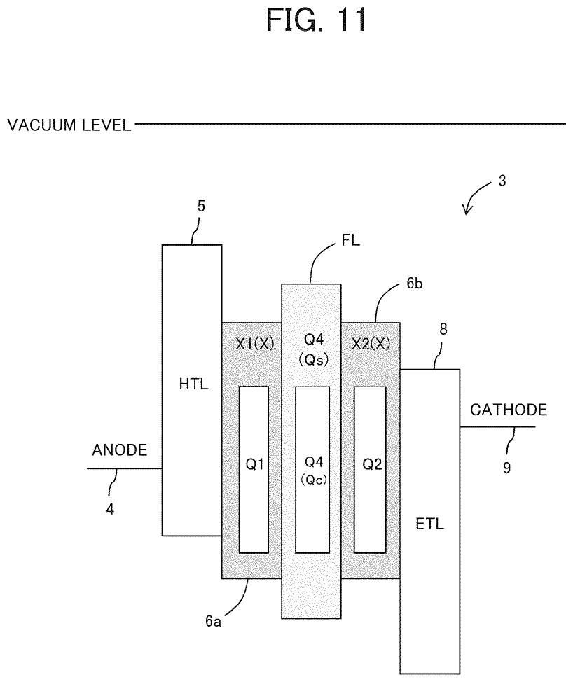

FIG. 11 is an energy band diagram of yet another light-emitting element according to this embodiment. In the light-emitting element 3 of FIG. 11, the first intermediate layer FL includes: the plurality of fourth quantum dots Q4 having a core-shell structure and emitting light in the same color as a color of light emitted from the plurality of the first quantum dots Q1. Each of the plurality of fourth quantum dots Q4 has a shell Qs higher in ionization potential, and lower in electron affinity, than the plurality of first quantum dots Q1, the plurality of second quantum dot quantum dots Q2, the first inorganic matrix material X1, and the second inorganic matrix material X2. The first quantum dots Q1 and the second quantum dots Q2 may have the same characteristic in emitting light (i.e., may be formed of the same material and in the same structure). The first quantum dots Q1 and the second quantum dots Q2 may be either core-shell quantum dots or shell-less (core-exposing) quantum dots. The first quantum dots Q1, the second quantum dots Q2, and the fourth quantum dots Q4 may have the same cores Qc (i.e., the cores Qc may be formed of the same material and in the same structure). The first inorganic matrix material X1 and the second inorganic matrix material X2 may be formed of the same material (i.e., may be formed in the same bandgap structure). Note that the display device including the light-emitting element of FIG. 11 has a configuration as follows. In FIG. 1, the first intermediate layer FL contains the plurality of fourth quantum dots Q4 having a core-shell structure.

In FIG. 11, the shells Qs of the fourth quantum dots Q4 serve as an energy barrier against both the electrons and the holes with respect to the first and second inorganic matrix materials X1 and X2. Such a feature successfully reduces a reactive current that runs through the inorganic matrix material X as a carrier path (i.e., a reactive current that does not pass through the quantum dots).

Whereas, the carriers are readily injected into the cores Qc of the fourth quantum dots Q4 in the first intermediate layer FL, thereby increasing a chance of recombination in (i.e., a change of light emission from) the fourth quantum dots Q4. The fourth quantum dots Q4 are away from the hole transport layer 5 and the electron transport layer 8. Such a feature successfully reduces occurrence of quenching.

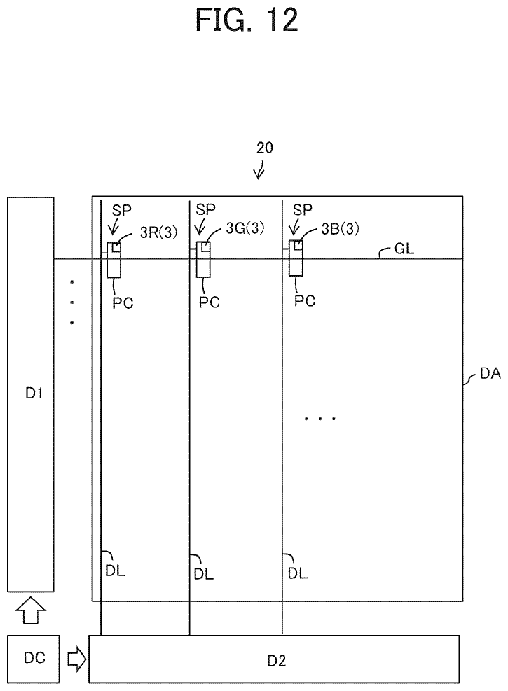

FIG. 12 is a schematic view illustrating an exemplary configuration of the display device according to this embodiment. As illustrated in FIG. 12, the display device 20 includes: a display unit DA including a plurality of subpixels SP; a first driver D1 and a second driver D2 that drive the plurality of subpixels SP; and a display control unit DC that controls the first driver D1 and the second driver D2. Each of the subpixels SP includes: the light-emitting element 3; and a pixel circuit PC connected to the light-emitting element 3. A red subpixel SP may have a light-emitting element 3R(3) that emits a red light. A green subpixel SP may have a light-emitting element 3G(3) that emits a green light. A blue subpixel SP may have a light-emitting element 3B(3) that emits a blue light. The pixel circuit PC may be connected to a scan signal line GL and a data signal line DL. The scan signal line GL may be connected to the first driver D1, and the data signal line DL may be connected to the second driver D2.

Each of the above-described embodiments is presented not for limitative purposes but for illustrative and descriptive purposes. It will be apparent to those skilled in the art that many variations are applicable in accordance with these illustrations and descriptions.

1. A light-emitting element, comprising:
a first electrode and a second electrode;
a first light-emitting layer provided between the first electrode and the second electrode, and containing a plurality of first quantum dots and a first inorganic matrix material filling spaces between the plurality of first quantum dots;
a second light-emitting layer provided between the second electrode and the first light-emitting layer, and containing a plurality of second quantum dots and a second inorganic matrix material filling spaces between the plurality of second quantum dots, the second quantum dots emitting light in a same color as a color of light emitted from the plurality of first quantum dots; and
a first intermediate layer provided between the first light-emitting layer and the second light-emitting layer.

2. The light-emitting element according to claim 1,
wherein the first intermediate layer has a higher ionization potential than the plurality of first quantum dots, the first inorganic matrix material, the plurality of second quantum dots, and the second inorganic matrix material.

3. The light-emitting element according to claim 1,
wherein the first intermediate layer has a lower electron affinity than the plurality of first quantum dots, the first inorganic matrix material, the plurality of second quantum dots, and the second inorganic matrix material.

4. (canceled)

5. The light-emitting element according to claim 1,
wherein the first electrode is an anode, and
the first inorganic matrix material has a lower ionization potential than the second inorganic matrix material.

6. The light-emitting element according to claim 1,
wherein the first electrode is an anode, and
the first inorganic matrix material has a lower electron affinity than the second inorganic matrix material.

7. (canceled)

8. The light-emitting element according to claim 1,
wherein the first intermediate layer contains a metal element and a nonmetal element both contained in common in the first inorganic matrix material and the second inorganic matrix material.

9. The light-emitting element according to claim 1, further comprising:
a third light-emitting layer provided between the second electrode and the second light-emitting layer, and containing a plurality of third quantum dots and a third inorganic matrix material filling spaces between the plurality of third quantum dots, the third quantum dots emitting light in a same color as the color of the light emitted from the plurality of first quantum dots; and
a second intermediate layer provided between the second light-emitting layer and the third light-emitting layer.

10. The light-emitting element according to claim 9,
wherein the first electrode is an anode and the second electrode is a cathode,
the first intermediate layer has a lower electron affinity than the plurality of first quantum dots, the first inorganic matrix material, the plurality of second quantum dots, the second inorganic matrix material, the plurality of third quantum dots, and the third inorganic matrix material, and
the second intermediate layer has a higher ionization potential than the plurality of first quantum dots, the first inorganic matrix material, the plurality of second quantum dots, the second inorganic matrix material, the plurality of third quantum dots, and the third inorganic matrix material.

11. The light-emitting element according to claim 10,
wherein the first intermediate layer has a lower electron affinity than the second intermediate layer, and
the first intermediate layer has a lower ionization potential than the second intermediate layer.

12. (canceled)

13. The light-emitting element according to claim 1,
wherein the first intermediate layer contains at least one selected from the group consisting of Al₂O₃, SiO₂, MgO, ZrO₂, HfO₂, Cr₂O₃, Ga₂O₃, Ta₂O₅, LiF, BaF₂, CaF₂, MgF₂, NaF, NaCl, CdF₂, CdCl₂, CdBr₂, CdI₂, ZnF₂, ZnCl₂, ZnBr₂, ZnI₂, ZnS, ZnMgS, ZnMgS₂, and MgS, and
the plurality of first quantum dots and the plurality of second quantum dots contain at least one selected from the group consisting of a II-VI semiconductor compound, a III-V semiconductor compound, and a IV semiconductor compound.

14. The light-emitting element according to claim 13,
wherein the group II-VI semiconductor compound contains at least one selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe,
the group III-V semiconductor compound contains at least one selected from the group consisting of GaAs, GaP, GaN, InN, InAs, InP and InSb, and
the group IV semiconductor compound contains at least one selected from the group consisting of Si and Ge.

15. (canceled)

16. The light-emitting element according to claim 1,
wherein the first intermediate layer is formed of an inorganic material containing a metal oxide, a metal halide, or a metal sulfide.

17. (canceled)

18. The light-emitting element according to claim 1, further comprising:
a first charge transport layer positioned between the first electrode and the first light-emitting layer, and containing an inorganic oxide semiconductor; and a second charge transport layer positioned between the second electrode and the second light-emitting layer, and containing an inorganic oxide semiconductor.

19. (canceled)

20. (canceled)

21. The light-emitting element according to claim 1,
wherein the plurality of first quantum dots and the plurality of second quantum dots are formed of a same material.

22. The light-emitting element according to claim 1,
wherein the first intermediate layer contains a plurality of fourth quantum dots configured to emit light in a same color as the color of the light emitted from the plurality of first quantum dots.

23. The light-emitting element according to claim 22,
wherein the first intermediate layer contains a fourth inorganic matrix material filling spaces between the plurality of fourth quantum dots.

24. The light-emitting element according to claim 23,
wherein the fourth inorganic matrix material has a higher ionization potential than the plurality of first quantum dots, the first inorganic matrix material, the plurality of second quantum dots, and the second inorganic matrix material.

25. The light-emitting element according to claim 23,
wherein the fourth inorganic matrix material has a lower electron affinity than the plurality of first quantum dots, the first inorganic matrix material, the plurality of second quantum dots, and the second inorganic matrix material.

26. The light-emitting element according to claim 22,
wherein each of the plurality of fourth quantum dots has a core-shell structure, and
each of the plurality of fourth quantum dots has a shell having a higher ionization potential than the plurality of first quantum dots, the first inorganic matrix material, the plurality of second quantum dots, and the second inorganic matrix material.

27. The light-emitting element according to claim 22,
wherein each of the plurality of fourth quantum dots has a core-shell structure, and
each of the plurality of fourth quantum dots has a shell having a lower electron affinity than the plurality of first quantum dots, the first inorganic matrix material, the plurality of second quantum dots, and the second inorganic matrix material.

28. (canceled)
